(19) United States
(12) Patent Application Publication
(10) Pub. No.: US 2023/0121954 A1
(43) Pub. Date: Apr. 20, 2023

(54) OPTOELECTRONIC PACKAGE STRUCTURE AND METHOD FOR MANUFACTURING THE SAME

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW)

(73) Assignee: Advanced Semiconductor Engineering, Inc., Kaohsiung (TW)

(21) Appl. No.: 17/503,229

(22) Filed: Oct. 15, 2021

(51) Int. Cl. H01S 5/024; H01S 5/026

(52) U.S. Cl. CPC H01S 5/02453; H01S 5/026; H01S 5/02476; H01L 33/64

(57) ABSTRACT

An optoelectronic package structure is provided. The optoelectronic package structure includes a heat source, a thermal conductive element, and a first optoelectronic component and a second optoelectronic component. The thermal conductive element is disposed over the heat source. The thermal conductive element defines a thermal conduction path P2 by which heat is transferred from the heat source to the thermal conductive element. The first optoelectronic component and the second optoelectronic component are arranged along an axis different from a thermal conduction path P2.

### BACKGROUND

### 1. Technical Field

The present disclosure relates generally to optoelectronic package structures and methods for manufacturing the same.

### 2. Description of the Related Art

The demand for network information has increased year by year due to implementations for cloud services, Internet of Things (IoT), 5G applications, etc. Such applications require high-speed data transmission. While operating at higher and higher speeds and frequencies, traditional cable transmission experience signal integrity issues due to the high impedance generated by capacitance and inductance of traditional cables. Signal integrity issues cause power loss and limit distance of transmission that can be achieved by traditional cables. In recent years, optical communication is often used in place of traditional cable transmission. Silicon photonics and optical engines, which include electronic integrated circuit (EIC) and a photonic integrated circuit (PIC), are applicable for optical communication. Accordingly, the data transmission is transformed from using electrons to using photons. For these and other reasons, various optoelectronic packages including the EIC and PIC have been developing.

### SUMMARY

In some arrangements, an optoelectronic package structure includes a heat source, a thermal conductive element, and a first optoelectronic component and a second optoelectronic component. The thermal conductive element is disposed over the heat source. The thermal conductive element defines a thermal conduction path P2 by which heat is transferred from the heat source to the thermal conductive element. The first optoelectronic component and the second optoelectronic component are arranged along an axis different from the thermal conduction path P2.

In some arrangements, an optoelectronic package structure includes a heat source, an optoelectronic component, and a thermal conductive element. The heat source has a first region and a second region at a side of the heat source. The optoelectronic component is disposed over the first region. The thermal conductive element is disposed over the second region and configured to receive heat from the heat source and transfer heat to outside of the thermal conductive element.

In some arrangements, an optoelectronic package structure includes a heat source and a plurality of optoelectronic components. The plurality of the optoelectronic components are configured to define a space adjacent to the first surface of the heat source. The space is configured to accommodate a thermal conductive element.

### BRIEF DESCRIPTION OF THE DRAWINGS

FIG. 1 illustrates a cross-sectional view of an optoelectronic package structure.

FIG. 2A illustrates a cross-sectional view of an optoelectronic package structure according to some arrangements.

FIG. 2B illustrates a top view of the optoelectronic package structure illustrated in FIG. 2A according to some arrangements.

FIG. 2C illustrates a bottom view of the optoelectronic package structure illustrated in FIG. 2A according to some arrangements.

FIG. 3 illustrates a cross-sectional view of an optoelectronic package structure according to some arrangements.

FIG. 4 illustrates a cross-sectional view of an optoelectronic package structure according to some arrangements.

FIG. 5A illustrates a cross-sectional view of an electronic package according to some arrangements.

FIG. 5B illustrates a bottom view of the optoelectronic package structure illustrated in FIG. 5A according to some arrangements.

FIG. 6A, FIG. 6B, FIG. 6C, FIG. 6D, and FIG. 6E illustrate a method for manufacturing an optoelectronic package structure according to some arrangements.

### DETAILED DESCRIPTION

As used herein, spatially relative terms, such as “top,” “bottom,” “beneath,” “below,” “above,” “over,” “on,” “upper,” “lower,” “left,” “right,” “vertical,” “horizontal,” “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein the term “active surface” may refer to a surface of an electronic component or passive element on which electrical or contact terminals such as contact pads, conductive studs or conductive pillars are disposed, for transmission of electrical signals or power. The term “active surface” may also refer to a surface of a photonic component along which a waveguide is disposed, and the waveguide may be disposed adjacent to the active surface. The term “inactive surface” may refer to another surface of the electronic component or passive element on which no electrical or contact terminals are disposed.

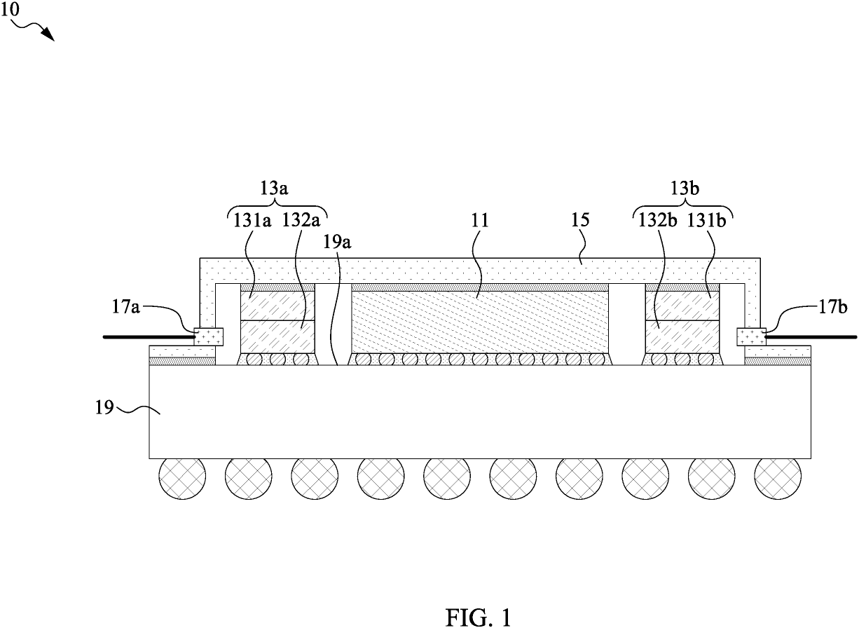

FIG. 1 illustrates a cross-sectional view of an optoelectronic package structure 10. The optoelectronic package structure 10 of FIG. 1 includes a host integrated circuit 11, a heat sink 15, a first optoelectronic component 13a, a second optoelectronic component 13b, an optical coupling element 17a, 17b, and a substrate 19. The first optoelectronic component 13a and the second optoelectronic component 13b may each include an electronic integrated circuit (EIC; 131a, 131b) and a photonic integrated circuit (PIC; 132a, 132b).

The host integrated circuit 11, the first optoelectronic component 13a, and the second optoelectronic component 13b are disposed over a surface 19a of the substrate 19. The host integrated circuit 11, the first optoelectronic component 13a, and the second optoelectronic component 13b are disposed laterally on the surface of the substrate 19 across an axis parallel to the surface 19a. The host integrated circuit 11 electrically connects the first optoelectronic component 13a and the second optoelectronic component 13b through the substrate 19. The heat sink 15 is disposed on the surface 19a of the substrate 19 and covers the host integrated circuit 11, the first photonic optoelectronic component 13a and the second photonic optoelectronic component 13b. As shown, the host integrated circuit 11, the first optoelectronic component 13a, and the second optoelectronic component 13b are between the heat sink 15 and the substrate 19. The heat sink 15 is thermally coupled to the host integrated circuit 11, the first photonic optoelectronic component 13a, and the second photonic optoelectronic component 13b so that heat generated from the host integrated circuit 11, the first photonic optoelectronic component 13a, and the second photonic optoelectronic component 13b may dissipate via the heat sink 15. As shown in FIG. 1, the heat sink 15 includes openings on its lateral surface(s) for accommodating the optical coupling elements 17a and 17b such that the optical coupling elements 17a and 17b can be disposed in the openings and align with the first optoelectronic component 13a and the second optoelectronic component 13b, respectively, along an axis parallel to the surface 19a to optically couple with the first photonic optoelectronic component 13a and the second photonic optoelectronic component 13b.

In the optoelectronic package structure 10 illustrated in FIG. 1, the host integrated circuit 11, the first photonic optoelectronic component 13a, and the second photonic optoelectronic component 13b are arranged adjacent to each other on a surface of the substrate 19 along an axis parallel to the surface 19a of the substrate 19 (i.e., lateral arrangement). Therefore, a large- size substrate is required, which may reduce the yield of the substrate. In addition, as compared to a vertical arrangement of the host integrated circuit and the optoelectronic component on the substrate, the lateral arrangement illustrated in FIG. 1 may increase the length of the electrical path between the host integrated circuit 11 and the electronic integrated circuit (e.g., 131a or 131b) of the optoelectronic component (e.g., 13a or 13b). In addition, to dissipate the heat generated from the host integrated circuit 11 and the optoelectronic component (e.g., 13a or 13b), the heat sink 15 is designed to have a large size to cover all heat-generating elements. As stated above, it is necessary to form openings in the heat sinks 15 for accommodating the optical coupling elements 17a and 17b, which further increases the process complexity and cost.

Some arrangements disclosed herein relate to an optoelectronic package structure including a heat source, a thermal conductive element, and a first optoelectronic component and a second optoelectronic component. The first optoelectronic component, the second optoelectronic component, and the thermal conductive element are disposed vertically with the heat source. Such optoelectronic package structure has a reduced size while maintaining heat dissipation efficiency and data transmission speed and can be produced in a simplified manufacturing process.

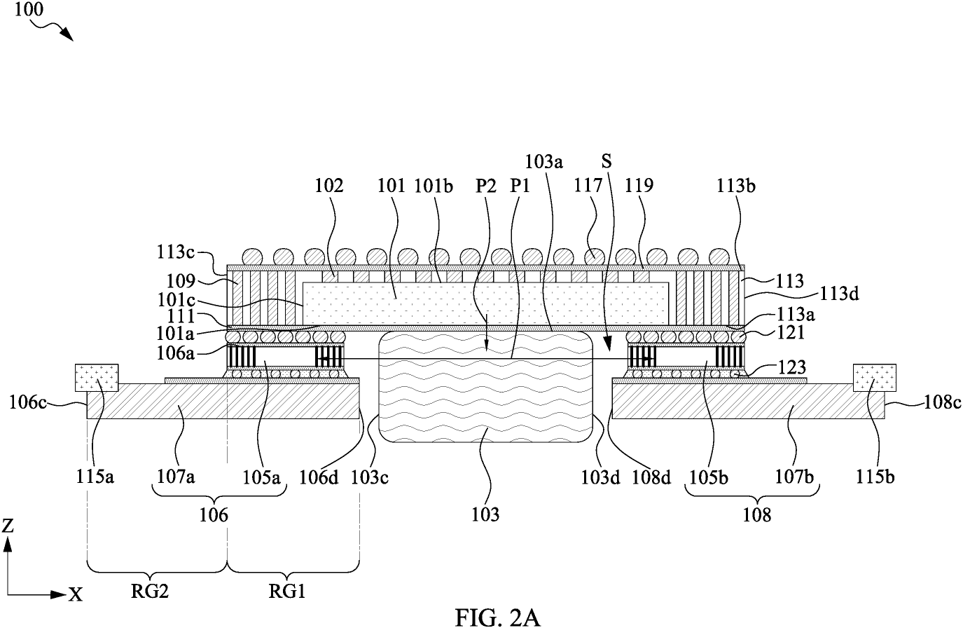

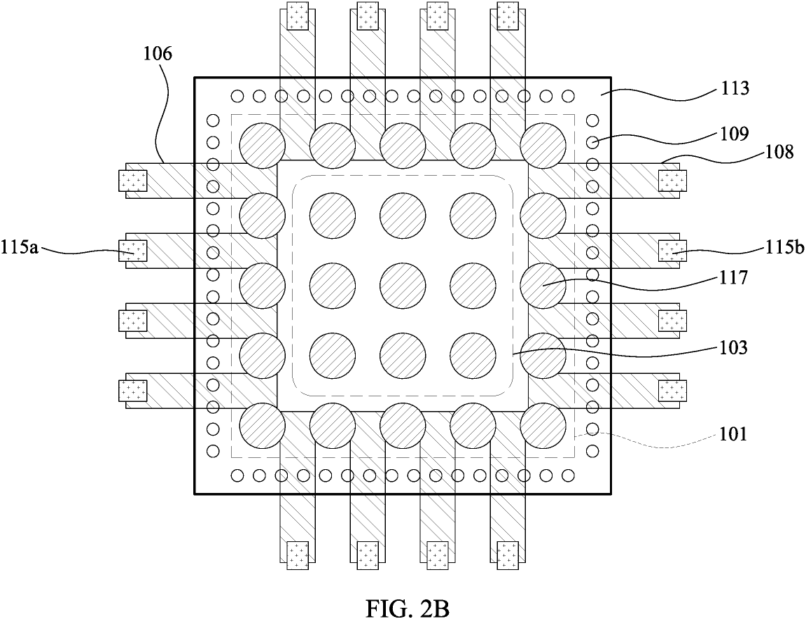

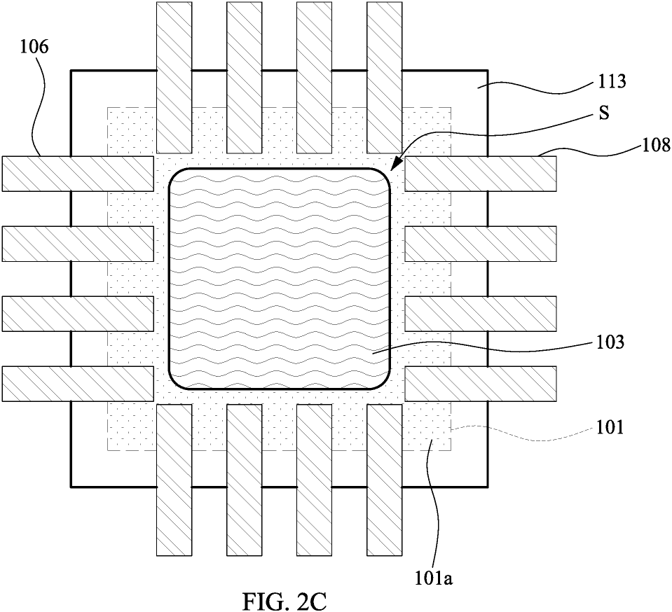

FIG. 2A illustrates a cross-sectional view of an optoelectronic package structure 100 according to some arrangements of the present disclosure. The optoelectronic package structure 100 of FIG. 2A includes a heat source 101, a thermal conductive element 103, a first optoelectronic component 106, and a second optoelectronic component 108.

The heat source 101 has a first surface 101a and a second surface 101b opposite to the first surface 101a. In some arrangements, the heat source 101 may be a component configured to control the first optoelectronic component 106 and the second optoelectronic component 108. In some arrangements, the first surface 101a is an inactive surface and the second surface is an active surface. The heat source consumes power during operation and generates heat in the process. In some arrangements, the heat source 101 may generate more heat than other components (e.g., the first optoelectronic component 106 and the second optoelectronic component 108) in the optoelectronic package structure. In some arrangements, the heat source 101 (during its normal operations) may have a temperature higher than its surroundings (or higher than other components in the optoelectronic package structure during their normal operations). In some examples, the heat source 101 may be a processing die, which includes, but not limited to, one or more of a central processing unit (CPU), a graphical processing unit (GPU), a field programmable gate array (FPGA), an application specific integrated circuit (ASIC), a switch ASIC, an Ethernet switch ASIC; or a memory die, which includes, but not limited to, a SRAM, DRAM, NAND, 3D NAND, Graphics Double Date Rate (GDDR) SDRAM, flash memory, a high bandwidth memory (HBM), or so on. The second surface 101b may be an active surface of the heat source.

The thermal conductive element 103 may be disposed adjacent to or on the first surface 101a, the second surface 101b, or both of the heat source 101. The thermal conductive element 103 is thermally coupled to the first surface 101a of the heat source 101. The thermal conductive element 103 may be electrically disconnected from the heat source 101. In some arrangements, the thermal conductive element 103 may be configured (e.g., sized, shaped, and formed of a material) to receive heat from the heat source 101 and transfer the heat to an external environment (e.g., air) outside of the thermal conductive element 103 or another component. In some arrangements, the thermal conductive element 103 may be configured to receive heat from the heat source 101 actively or passively. In some arrangements, the thermal conductive element 103 may be configured to transfer heat out of the heat source 101. The thermal conductive element 103 may be configured to dissipate heat away from the heat source 101. The thermal conductive element 103 may be configured to conduct heat along a thermal conduction path P2 between the heat source 101 and the thermal conductive element 103, for example, from the heat source 101 to the thermal conductive element 103. In other words, the arrangement of the thermal conductive element 103 and the heat source 101 define the thermal conduction path P2 by which the heat is transferred from the heat source 101 to the thermal conductive element 103. The thermal conduction path P2 may be the path with the overall best thermal conductivity. The thermal conduction path P2 may pass through a first redistribution layer 111 and/or an adhesive layer (such as a thermal conductive adhesive or a thermal interface material (TIM); not shown) disposed between the heat source 101 and the thermal conductive element 103. In some arrangements, the first redistribution layer 111 transfers heat from the heat source 101 to the thermal conductive element 103 but insulates against electrical conductivity. The thermal conduction path P2 may be substantially perpendicular to the first surface 101a of the heat source 101, a surface 103a of the thermal conductive element 103, or both as it may provide the shortest and most efficient heat transfer path from the heat source 101 to the thermal conductive element 103 across the entire surface of the surfaces 101a and 103a. In some arrangements where the thermal conductive element 103 is disposed adjacent to or on both of the first surface 101a and the second surface 101b of the heat source 101, the heat dissipation efficiency may be further improved compared to only one thermal conductive element 103 is disposed adjacent to or on the first surface 101a of the heat source 101.

The thermal conductive element 103 has a first lateral surface 103c and a second lateral surface 103d. The second lateral surface 103d may be opposite to the first lateral surface 103c. A projection area of the thermal conductive element 103 onto the first surface 101a of the heat source 101 along P2 may be smaller than a surface area of the first surface 101a of the heat source 101. In some examples, the surface 103a faces and is smaller than the first surface 101a. The thermal conductive element 103 may be or include a thermal conductive material, for example, a metal (e.g., copper or other metal or alloy), a metal oxide, a carbon material (e.g., carbon nanotube or graphene) and other suitable materials. In some arrangements, the thermal conductive material may include thermal conductive particles. In some arrangements, the thermal conductive element 103 may further include an adhesive material, for example, a polymer (e.g., silicon-based resin, epoxy-based resin, acrylic-based rein or other polymeric materials). In some arrangements, the thermal conductive element 103 may be or include a thermal conductive paste including, for example, a copper paste or a solder paste. The thermal conductive element 103 may be or include a thermal conductive adhesive or a thermal interface material (TIM). The thermal conductive element 103 may be, for example, a heat sink or a metal plate. In some arrangements, the thermal conductive element 103 is a copper heat sink.

The first optoelectronic component 106 and the second optoelectronic component 108 may be disposed adjacent to or on the first surface 101a, the second surface 101b, or both of the heat source 101. The first optoelectronic component 106 may be disposed adjacent to the first lateral surface 103c of the thermal conductive element 103, and the second optoelectronic component 108 may be disposed adjacent to the second lateral surface 103d of the thermal conductive element 103. The first optoelectronic component 106 and the second optoelectronic component 108 may be arranged along an axis or direction(s) P1 different from the thermal conduction path P2 between the heat source 101 and the thermal conductive element 103. In some arrangements, the axis P1 intersects or is transverse the thermal conduction path P2. In some arrangements, the axis P1 is substantially perpendicular to the thermal conduction path P2. In some arrangements, the axis P1 is oblique with respect to the thermal conduction path P2. For example, in some arrangements, the thermal conduction path P2 is along or parallel to the vertical direction (Z-direction), the axis P1 is along or parallel to the horizontal direction (X-direction), and P1 is substantially perpendicular to P2. A projection area of a first surface 106a of one of the first optoelectronic component 106 and the second optoelectronic component 108 in the vertical direction (z-direction) overlaps with at least a portion of the first surface 101a of the heat source 101.

In some arrangements, the first optoelectronic component 106, the second optoelectronic component 108 or both may be spaced away from the thermal conductive element 103 with a gap between the thermal conductive element 103 and the component 106/108. That is, the first optoelectronic component 106, the second optoelectronic component 108 or both does not physically contact the thermal conductive element 103. The first optoelectronic component 106 and the second optoelectronic component 108 may each include a separate electronic integrated circuit (105a or 105b) and a photonic integrated circuit (107a or 107b), respectively. The electronic integrated circuit 105a, 105b electrically connects to the photonic integrated circuit 107a, 107b, respectively, via an electrical connector 123 disposed therebetween. Examples of the electrical connector 123 include a pillar, a solder/stud bump, or a solderable element such as a solder ball). The electronic integrated circuits 105a, 105b may electrically connect to the heat source 101 via, for example, the first redistribution layer 111 and a first electrical connector 121 disposed therebetween. Examples of the first electrical connector 121 include a pillar, a solder/stud bump, or a solderable element such as a solder ball. In some arrangements, the electronic integrated circuit (105a or 105b) is disposed between the heat source 101 and the photonic integrated circuit (107a or 107b).

In some arrangements, the optoelectronic package structure 100 further comprises an encapsulant 113 covering at least a portion of the heat source 101. In some examples, the encapsulant 113 may surround at least a portion of the heat source 101. In some examples, the heat source 101 may be at least partially embedded in the encapsulant 113 with only the first surface 101a of the heat source 101 exposed from a first surface 113a of the encapsulant 113. The second surface 101b of the heat source 101 may be covered by and directly contacting the encapsulant 113. The through via or conductive pillar 109 may be disposed in the encapsulant 113. The through via or conductive pillar 109 may be disposed adjacent to one or both lateral surface(s) 101c of the heat source 101. The through via or conductive pillar 109 may extend from a first surface 113a of the encapsulant 113 to a second surface 113b of the encapsulant 113 and pass through the encapsulant 113. In some arrangements, the through via 109 is a through molding via (TMV).

In some arrangements, the optoelectronic package structure 100 further comprises a second electrical connector 102 disposed directly on or adjacent to the second surface 101b of the heat source 101. The second electrical connector 102 may be a pillar, a solder/stud bump, a conductive via, or so on. The second electrical connector 102 may be at least partially embedded in the encapsulant 113 and exposed from the second surface 113b of the encapsulant 113. The second electrical connector 102 may extend from the second surface 113b of the encapsulant 113 to the second surface 101b of the heat source 101. The second electrical connector 102 may penetrates the encapsulant 113, i.e., from the second surface 113b of the encapsulant 113 to a surface of the encapsulant 113 in contact the second surface 101b of the heat source 101. The heat source 101 electrically connects to the second electrical connector 102.

In some arrangements, the first optoelectronic component 106 and the second optoelectronic component 108 are located below the encapsulant 113. In some arrangements, the surface 113a of the encapsulant 113 face at least a portion of the first optoelectronic component 106 and at least a portion of the second optoelectronic component 108 in a direction parallel to P2 and perpendicular to the surface 113a. In some arrangements, the electronic integrated circuit 105a of the first optoelectronic component 106 and the electronic integrated circuit 105b of the second optoelectronic component 108 are located directly below the encapsulant 113 in a direction parallel to P2 and perpendicular to the surface 113a. As illustrated in FIG. 2A, the first optoelectronic component 106 may extend beyond a first lateral surface 113c of the encapsulant 113 in a direction parallel to P1 and the second optoelectronic component 108 may extend beyond a second lateral surface 113d of the encapsulant 113 in a direction parallel to P1. The encapsulant 113 may include an epoxy resin having fillers, a molding compound (e.g., an epoxy molding compound or other molding compounds), polyimide, a phenolic compound or material, a material with a silicone dispersed therein, or a combination thereof.

In some arrangements, the optoelectronic package structure 100 further includes the first redistribution layer 111 disposed between the heat source 101 and the first optoelectronic component 106 and between the heat source 101 and the second optoelectronic component 108. The first redistribution layer 111 may cover at least a portion of the first surface 113a of the encapsulant 113. The first redistribution layer 111 may be disposed on the first surface 113a of the encapsulant 113 and extend laterally from a first lateral surface 113c of the encapsulant 113 to a second lateral surface 113d of the encapsulant 113 opposite to the first lateral surface 113c along a direct parallel to P1. Thus, the first redistribution layer 111 may also be disposed between the heat source 101 and the thermal conductive element 103. The first redistribution layer 111 may include one or more conductive structure and one or more dielectric layer.

In some arrangements, the optoelectronic package structure 100 further includes a second redistribution layer 119 disposed adjacent to the second surface 113b of the encapsulant 113. The second redistribution layer 119 may cover at least a portion of the second surface 113b of the encapsulant 113. The second redistribution layer 119 may be disposed on the second surface 113b of the encapsulant 113 and extend laterally from a first lateral surface 113c of the encapsulant 113 to a second lateral surface 113d of the encapsulant 113 opposite to the first lateral surface 113c along a direct parallel to P1. The second redistribution layer 119 may electrically connect to the second electrical connector 102 and the through via or conductive pillar 109. In some arrangements, the electronic integrated circuits 105a, 105b may electrically connect to the heat source 101 using, for example, the first electrical connector 121, the first redistribution layer 111, the through via or conductive pillar 109, the second redistribution layer 119 and the second electrical connector 102.

In some arrangements, one or more first electrical contact 117 may be further disposed adjacent to or on the second surface 113b of the encapsulant 113. The first electrical contact 117 may electrically connect to the second redistribution layer 119 for providing external electrical connection. The first electrical contact 117 may be, for example, a solderable element (e.g., a solder ball).

In some arrangements, the optoelectronic package structure 100 further comprises optical components 115a and 115b optically coupled to the first optoelectronic component 106 and the second optoelectronic component 108, respectively. In some arrangements, the optical components 115a and 115b are optically coupled to the photonic integrated circuit 107a of the first optoelectronic component 106 and the photonic integrated circuit 107b of the second optoelectronic component 108, respectively. The optical components 115a and 115b may be disposed adjacent to a first lateral surface 106c of the first optoelectronic component 106 and a first lateral surface 108c of the second optoelectronic component 108, respectively. As shown, the thermal conductive element 103 may be disposed adjacent to a second lateral surface 106d of the first optoelectronic component 106 (opposite to the first lateral surface 106c of the first optoelectronic component 106) and a second lateral surface 108d of the second optoelectronic component 108 (opposite to the first lateral surface 108c of the second optoelectronic component 108). In some arrangements, the optical components 115a and 115b may be or include optical fibers or laser diodes. In some arrangements, the optical components 115a and 115b may be an optical fiber array unit or an optical fiber array unit surrounded by a housing.

In some arrangements, the optoelectronic components 106 or 108 and the thermal conductive element 103 are arranged adjacent to each other on or adjacent to the first surface 101a of the heat source 101. In some arrangements, each of one or both of the optoelectronic components 106 and 108 may have a first region RG1 covered by a projection of the encapsulant 113 along a direction parallel to P2 from a top view (i.e., in or parallel to the z-direction) and a second region RG2 outside such projection of the encapsulant 113. In some arrangements, the electronic integrated circuit 105a or 105b of each or both of the optoelectronic components 106 and 108 is located within the first region RG1 and the photonic integrated circuit 107a or 107b of each or both of the optoelectronic components 106 and 108 has a portion electrically connected to the electronic integrated circuit 105a or 105b of each or both of the optoelectronic components 106 and 108 at the first region RG1 and a portion optically coupled with the optical component 115a or 115b at the second region RG2.

By disposing the first optoelectronic component 106 and the second optoelectronic component 108 with the heat source 101 vertically, rather than laterally as illustrated in FIG. 1, less surface area of a substrate or carrier (e.g., substrate 19 shown in FIG. 1) is needed for accommodating these components. Thus, a smaller substrate or carrier may be utilized, which may improve yield as a smaller substrate may have less yield loss compared to a larger one. In addition, given that the first optoelectronic component 106 and the second optoelectronic component 108 are disposed vertically with respect to the heat source 101 along or parallel to P2 and electrically connect with the heat source 101 through the through via or conductive pillar 109, the signal transmission path between the heat source 101 and the first optoelectronic components 106 and 108 may be shorter than the signal transmission path of the structure illustrated in FIG. 1, which passes through the substrate 19. In some cases, given that the heat source 101 can be thinned, e.g., ground from the back surface (i.e., inactive surface such as the surface 101a), a shorter through via or conductive pillar 109 can be utilized, and thus the signal transmission path can be further reduced. Moreover, in the optoelectronic package structure 100 illustrated in FIG. 2A, because most of the heat is generated from the heat source 101, the disposal of the thermal conductive element 103 directly under the heat source 101 and being in close contact with the heat source 101 can effectively dissipate heat from the optoelectronic package structure 100. In addition, the heat generated from the optoelectronic components 106 and 108 may be transferred to the heat source 101 through the redistribution layer 111, which can further increases the overall heat dissipation efficiency. As a result, the size of the optoelectronic package structure may be reduced compared to that illustrated in FIG. 1 because the thermal conductive element 103 needs not to cover the first optoelectronic component 106 and the second optoelectronic component 108 as the heat sink 15 illustrated in FIG. 1 does. The thermal conductive element 103 can be accommodated in a space S defined by the first optoelectronic component 106, the second optoelectronic component 108, and the heat source 101. In other words, the space S is sized and shaped to accommodate a size and shape of the thermal conductive element 103. Accordingly, the size of the thermal conductive element 103 can be reduced. Furthermore, the manufacturing process may be simplified compared to that for the structure illustrated in FIG. 1 because the thermal conductive element 103 is not required to contact the first optoelectronic component 106 and the second optoelectronic component 108 as the heat sink 15 illustrated in FIG. 1 does. The optical components 115a and 115b can be optically coupled to the first optoelectronic component 106 and the second optoelectronic component 108 without passing through the heat sink 15 illustrated in FIG. 1.

FIG. 2B illustrates a top view of the optoelectronic package structure 100 illustrated in FIG. 2A according to some arrangements of the present disclosure. It should be noted that some elements or components are omitted in FIG. 2B for clarity.

A plurality of the first optoelectronic components 106 and a plurality of the second optoelectronic components 108 may be included in the optoelectronic package structure 100. The plurality of the first optoelectronic components 106 and the plurality of the second optoelectronic components 108 may be disposed at or along a peripheral region of the first surface 101a or the second surface 101b of the heat source 101. The plurality of the first optoelectronic components 106 and the plurality of the second optoelectronic components 108 may surround the thermal conductive element 103. The plurality of the first optoelectronic components 106 and the plurality of the second optoelectronic components 108 may surround the heat source 101 as shown in the top view in FIG. 2B. The plurality of the first optoelectronic components 106 and the plurality of the second optoelectronic components 108 may be disposed symmetrically with respect to a geographical center of the thermal conductive element 103. The thermal conduction path

FIG. 2C illustrates a bottom view of the optoelectronic package structure 100 illustrated in FIG. 2A according to some arrangements of the present disclosure. It should be noted that some elements or components are omitted in FIG. 2C for clarity.

The plurality of the first optoelectronic components 106 and the plurality of the second optoelectronic components 108 may be arranged in a manner such that they define a space S on or adjacent the first surface 101a of the heat source 101 for accommodating the thermal conductive element 103.

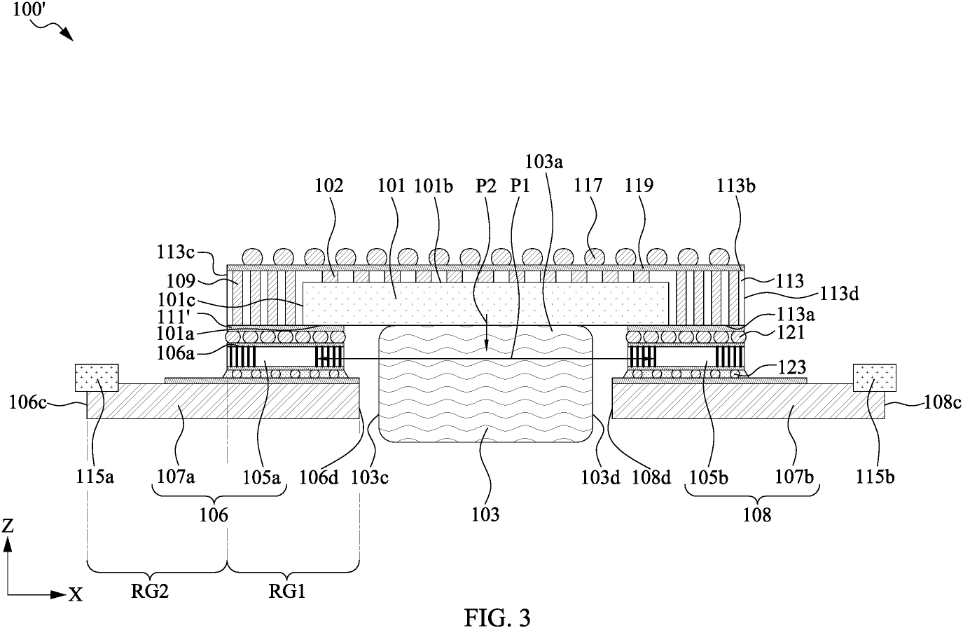

FIG. 3 illustrates a cross-sectional view of an optoelectronic package structure 100′ according to some arrangements of the present disclosure. The optoelectronic package structure 100′ is similar to the optoelectronic package structure 100 in FIG. 2A, and the differences therebetween are described as follows.

In the optoelectronic package structure 100′, the redistribution layer 111′ is disposed between the heat source 101 and the first optoelectronic component 106 and between the heat source 101 and the second optoelectronic component 108. The redistribution layer 111′ may be disposed around a peripheral region of the heat source 101. There is no redistribution layer 111′ between the heat source 101 and the thermal conductive element 103. The thermal conductive element 103 can be directly disposed below the heat source 101 or attached to the heat source 101 via a thermal conductive adhesive or a thermal interface material (not shown) between the heat source 101 and the thermal conductive element 103.

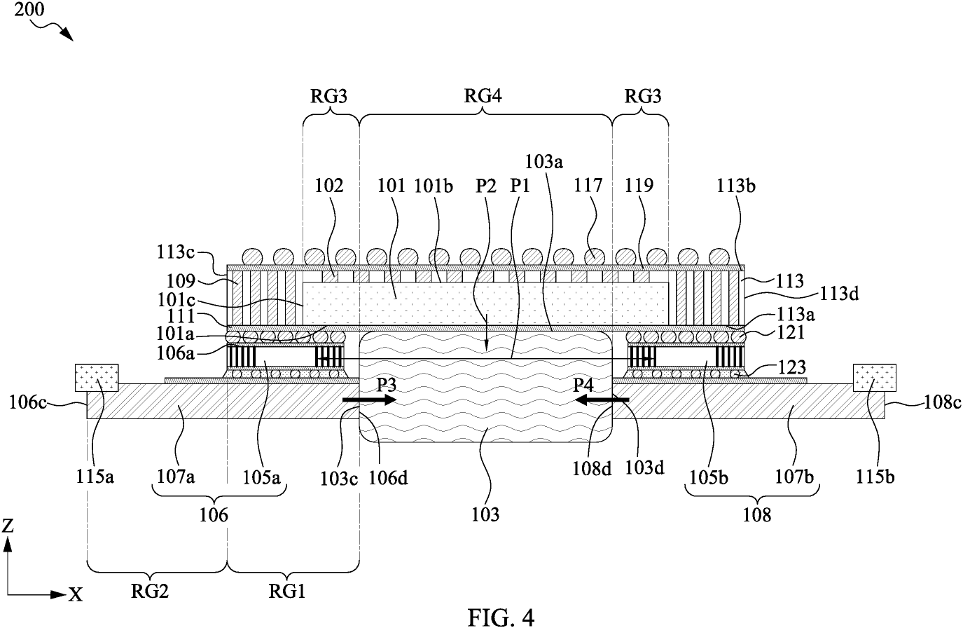

FIG. 4 illustrates a cross-sectional view of an optoelectronic package structure 200 according to some arrangements of the present disclosure. The optoelectronic package structure 200 is similar to the optoelectronic package structure 100 in FIG. 2A, and the differences therebetween are described as follows.

In the optoelectronic package structure 200, the heat source 101 has a region RG3 and a region RG4 at a side (e.g., the first surface 101a) of the heat source 101. The first optoelectronic component 106 and/or the second optoelectronic component 108 may be disposed over the region RG3 along or parallel to P2 and the thermal conductive element 103 may be disposed over the region RG4 along or parallel to P2. The first optoelectronic component 106, the second optoelectronic component 108 or both may be in direct physical contact with the thermal conductive element 103. In some arrangements, the thermal conductive element 103 is configured to provide a thermal conduction paths P3, P4 for the first and second optoelectronic components 106 and 108, respectively. As a result, heat generated from the first and second optoelectronic components 106 and 108 can be directly transferred to the thermal conductive element 103 without passing through the heat source 101 or the first redistribution layer 111. The thermal conduction paths P3, P4 may be substantially perpendicular or transverse to the thermal conduction path P2. In some arrangements, the thermal conduction paths P3, P4 may be oblique to the thermal conduction path P2.

In other arrangements not shown, the thermal conductive element 103 may be configured to receive heat from the heat source 101, but not from the first and second optoelectronic components 106 and 108. In such arrangements, the first and second optoelectronic components 106 and 108 may be spaced apart from the thermal conductive element 103 with a gap therebetween to avoid heat entering the first and second optoelectronic components 106 and 108 through the thermal conductive element 103. Alternatively, the thermal-sensitive elements, such as laser diode, can be disposed outside the first and second optoelectronic components 106 and 108 (for example, as a remote laser diode) to avoid the failure caused by heat entering through the thermal conductive element 103.

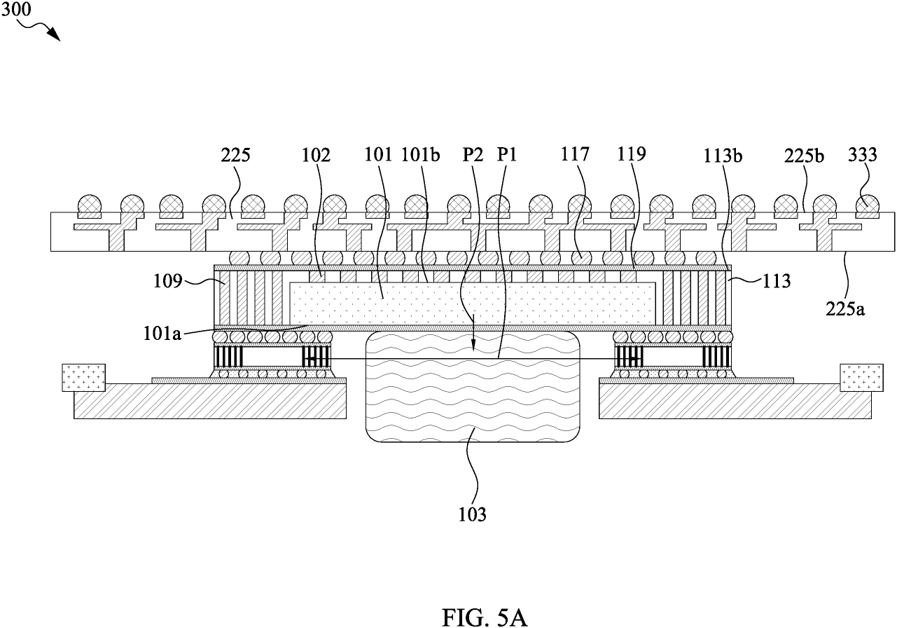

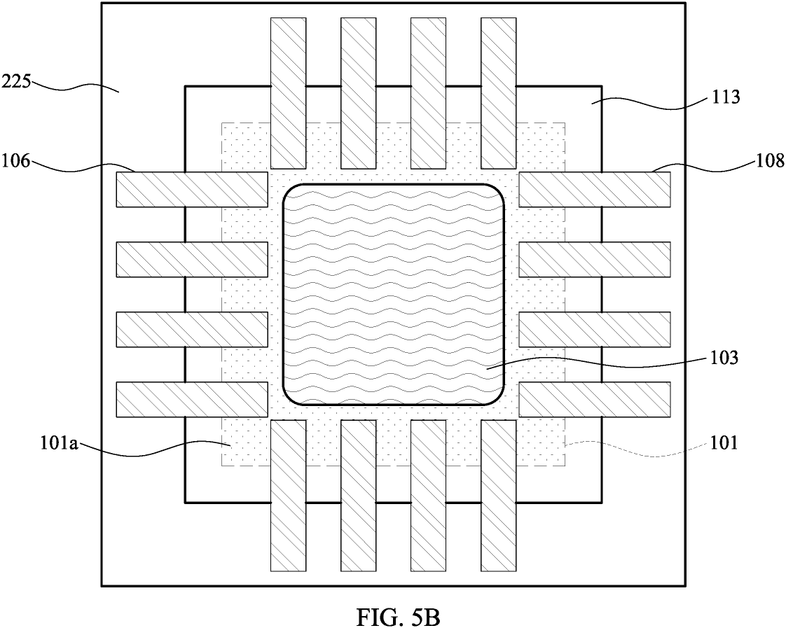

FIG. 5A illustrates a cross-sectional view of an electronic package 300 according to some arrangements of the present disclosure. The electronic package 300 illustrated in FIG. 5A is similar to that illustrated in FIG. 2A with a difference being that a carrier 225 may be further disposed adjacent to the second surface 101b of the heat source 101. The carrier 225 may be disposed adjacent to the second surface 113b of the encapsulant 113. The carrier 225 may electrically connect to the heat source 101 via the second surface 101b of the heat source 101. The carrier 225 may electrically connect to the heat source 101 via the first electrical contact 117, the redistribution layer 119, and the second electrical connector 102. The carrier 225 has a first surface 225a and a second surface 225b opposite to the first surface 225a. A thermal conductive element (e.g., the thermal conductive element 103 shown in FIG. 2A) may be disposed adjacent to the second surface 225b of the carrier 225 to improve heat dissipation efficiency of heat transferred through the carrier 225. The carrier 225 may include one or more conductive traces or vias disposed in or within one or more dielectric layers. The one or more conductive traces or vias transmit electrical signals from the first surface 225a of the substrate 225 to a second surface 225b of the substrate 225 opposite to the first surface 225a. The carrier 225 may be a substrate, a printed circuit board, an interposer, a redistribution layer, a fan-out substrate, or so on.

In some arrangements, at least one second electrical contact 333 may be further disposed directly on or adjacent to the second surface 225b of the substrate 225 for providing external electrical connection. The second electrical contact 333 may be, for example, a solderable element (e.g., a solder ball).

FIG. 5B illustrates a bottom view of the optoelectronic package structure 300 illustrated in FIG. 5A according to some arrangements of the present disclosure. It should be noted that some elements or components are omitted in FIG. 5B for clarity.

In some arrangements, a method for manufacturing an optoelectronic package structure includes disposing a plurality of optoelectronic components on a first surface of a heat source; and disposing a thermal conductive element on the first surface of the heat source.

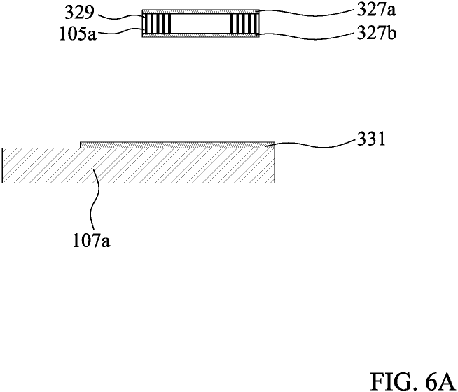

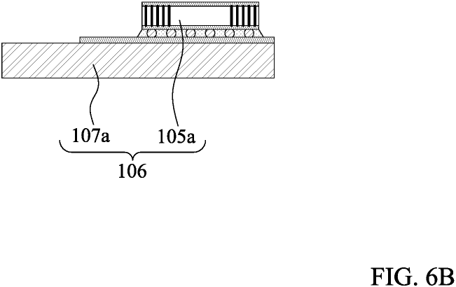

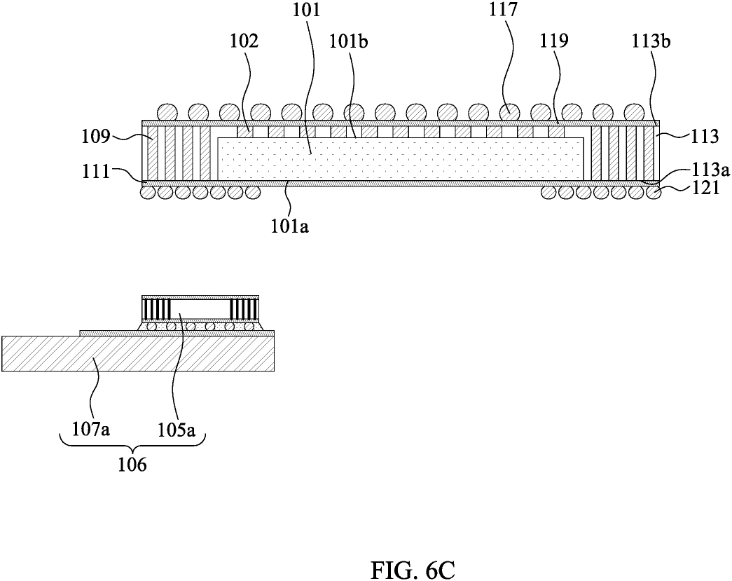

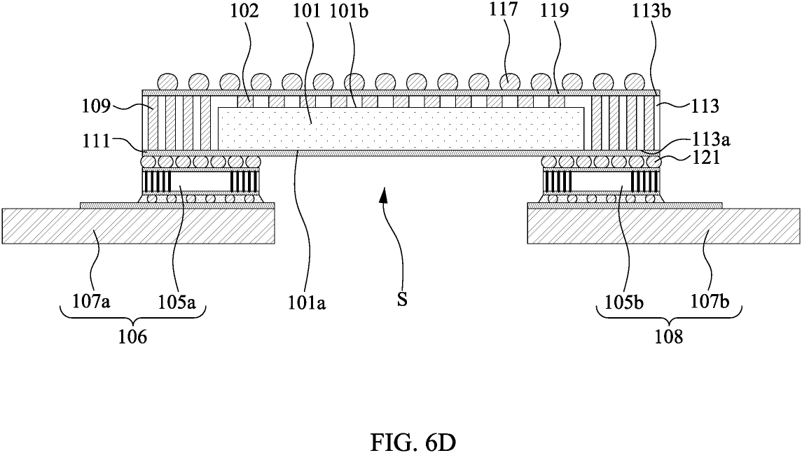

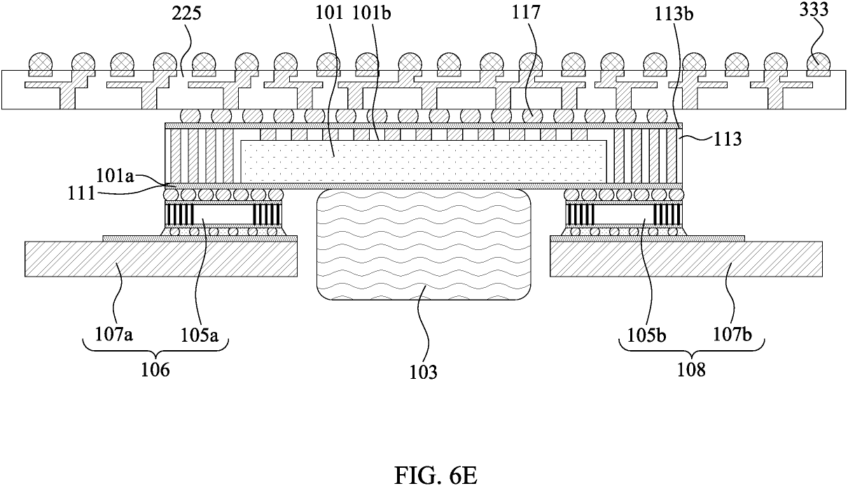

FIGS. 6A-6E illustrate a method of manufacturing an optoelectronic package structure such as the optoelectronic package structure of FIG. 2A.

Referring to FIG. 6A, an electronic integrated circuit 105a and a photonic integrated circuit 107a are provided or otherwise manufactured. The electronic integrate circuit 105a may include a conductive through via 329 extending from a top surface to a bottom surface of the electronic integrate circuit 105a, a redistribution layer 327a disposed on the top surface, and a redistribution layer 327b on the bottom surface. The conductive through via 329 may be a through silicon via (TSV). The photonic integrated circuit 107a may include a redistribution layer 331 on its active surface.

Referring to FIG. 6B, the electronic integrated circuit 105a is disposed on the photonic integrated circuit 107a, for example, by flip-chip bonding, to form an optoelectronic component 106. The electronic integrated circuit 105a may electrically connect to the photonic integrated circuit 107a through the redistribution layer 327b of the electronic integrated circuit 105a and the redistribution layer 331 of the photonic integrated circuit 107a. Although not shown in FIG. 6B, the optoelectronic component 108 can be manufactured similarly.

Referring to FIG. 6C, a heat source 101, such as an ASIC, is provided. The heat source 101 may be encapsulated by an encapsulant 113. One or more through conductive vias 109 are formed within the encapsulant 113 and penetrates from a top surface 113b to a bottom surface 113a of the encapsulant 113. One or more electrical connectors 102 (such as conductive vias or bumps) are formed with the encapsulant 113 and penetrates from the top surface 113b of the encapsulant 113 to a surface of the encapsulant 113 in contact with a top surface 101b of the heat source 101. The redistribution layers 119 and 111 are disposed on the top surface 113b and the bottom surface 113a of the encapsulant 113, respectively. One or more electrical contact 117 are disposed on the redistribution layer 119, and one or more electrical connectors 121 may be disposed on the redistribution layer 111.

Referring to FIG. 6D, at least one first optoelectronic component 106 and at least one second optoelectronic component 108 are disposed adjacent to a bottom surface 113a of the encapsulant 113 and a bottom surface 101a of the heat source 101. The first optoelectronic components 106 and the second optoelectronic components 108 are disposed in a manner such that they define a space S on the bottom surface 101a of the heat source 101 for accommodating a thermal conductive element 103.

Referring to FIG. 6E, a thermal conductive element 103 is disposed over the bottom surface 101a of the heat source 101 and within the space S defined by the first optoelectronic components 106, the second optoelectronic components 108, and the first surface 101a of the heat source 101. In addition, a substrate 225 is disposed adjacent to the top surface 113b of the encapsulant 113 and is electrically connected to at least one electrical contact 117. Afterwards, an optoelectronic package structure (e.g., an optoelectronic package structure 200 as is illustrated in of FIG. 2A) may be obtained.

As used herein and not otherwise defined, the terms “substantially” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a line or a plane can be substantially flat if a peak or depression of the line or plane is no greater than 5 µm, no greater than 1 µm, or no greater than 0.5 µm.

As used herein, the singular terms “a,” “an,” and “the” may include plural referents unless the context clearly dictates otherwise. In the description of some arrangements, a component provided “on or “over” another component can encompass cases where the former component is directly on (e.g., in physical contact with) the latter component, as well as cases where one or more intervening components are located between the former component and the latter component.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, subdivided, or reordered to form an equivalent method without departing from the teachings of the present disclosure. Accordingly, unless specifically indicated herein, the order and grouping of the operations are not limitations.

What is claimed is:

1. An optoelectronic package structure, comprising:
a heat source;
a thermal conductive element disposed over the heat source, wherein the thermal conductive element defines a thermal conduction path P2 by which heat is transferred from the heat source to the thermal conductive element; and
a first optoelectronic component and a second optoelectronic component, wherein the first optoelectronic component and the second optoelectronic component are arranged along an axis different from the thermal conduction path P2.

2. The optoelectronic package structure of claim 1, wherein the axis intersects the thermal conduction path.

3. The optoelectronic package structure of claim 1, wherein the first optoelectronic component and the thermal conductive element are disposed over a first surface of the heat source.

4. The optoelectronic package structure of claim 3, further comprising a carrier disposed adjacent to a second surface of the heat source that is opposite to the first surface.

5. The optoelectronic package structure of claim 1, wherein the first optoelectronic component electrically connects to the heat source.

6. The optoelectronic package structure of claim 5, wherein the first optoelectronic component comprises an electronic integrated circuits.

7. The optoelectronic package structure of claim 1, wherein in a cross-sectional view the first optoelectronic component is disposed adjacent to a first lateral surface of the thermal conductive element and the second optoelectronic component is disposed adjacent to a second lateral surface of the thermal conductive element, wherein the first lateral surface is opposite to the second lateral surface.

8. An optoelectronic package structure, comprising:
a heat source having a first region and a second region at a side of the heat source;
an optoelectronic component disposed over the first region; and
a thermal conductive element disposed over the second region, wherein the thermal conductive element is configured to receive heat from the heat source and transfer heat to outside of the thermal conductive element.

9. The optoelectronic package structure of claim 8, wherein the thermal conductive element defines a thermal conduction path for the optoelectronic component, and wherein the thermal conduction path does not pass through the heat source.

10. The optoelectronic package structure of claim 9, wherein the thermal conductive element contacts the optoelectronic component.

11. The optoelectronic package structure of claim 8, wherein the optoelectronic component is electrically coupled to the heat source.

12. The optoelectronic package structure of claim 11, wherein the heat source comprises a process unit.

13. The optoelectronic package structure of claim 8, wherein the optoelectronic component comprises an electronic integrated circuit and a photonic integrated circuit.

14. The optoelectronic package structure of claim 13, wherein the electronic integrated circuit is disposed between the heat source and the photonic integrated circuit.

15. The optoelectronic package structure of claim 9, further comprising an optical component, wherein the optical component is optical coupled to the optoelectronic component at a first side of the optoelectronic component, and the thermal conductive element is disposed adjacent to a second side of the optoelectronic component different form the first side of the optoelectronic component.

16. An optoelectronic package structure, comprising:
a heat source having a first surface; and
a plurality of optoelectronic components configured to define a space adjacent to the first surface of the heat source, wherein the space is configured to accommodate a thermal conductive element.

17. The optoelectronic package structure of claim 16, further comprising a thermal conductive element configured to receive heat generated from the heat source.

18. The optoelectronic package structure of claim 17, wherein the plurality of the optoelectronic components and the thermal conductive element are arranged adjacent to each other on the first surface of the heat source.

19. The optoelectronic package structure of claim 17, wherein the plurality of the optoelectronic components are disposed symmetrically with respect to a geographical center of the thermal conductive element.

20. The optoelectronic package structure of claim 16, wherein the plurality of the optoelectronic components surround the heat source.
